(19) United States
(12) Patent Application Publication
(10) Pub. No.: US 2015/0077190 A1
(43) Pub. Date: Mar. 19, 2015

(54) PACKAGE STRUCTURE OF CRYSTAL OSCILLATOR WITH EMBEDDED THERMISTOR

(71) Applicant: TXC CORPORATION, Taipei (TW)

(72) Inventors: CHIEN-WEI CHIANG, TAO YUAN COUNTY (TW); TING YEH, TAO YUAN COUNTY (TW)

(73) Assignee: TXC CORPORATION, Taipei (TW)

(21) Appl. No.: 14/104,392

(22) Filed: Dec. 12, 2013

(30) Foreign Application Priority Data
Sep. 13, 2013 (TW) 102133155

(51) Int. Cl. H03B 1/02

(52) U.S. Cl. CPC H03B 1/02
USPC 331/66

(57) ABSTRACT

A package structure of crystal oscillator with embedded thermistor is disclosed. The package structure comprises a ceramic substrate. A crystal oscillation device is mounted in the accommodation space of the ceramic substrate. A cover is used to seal the accommodation space. At least one thermistor is embedded in the ceramic substrate. A patterned metal interconnection in the ceramic substrate is electrically connected with the crystal oscillation device and the thermistor, respectively. The present invention describes as follows: the thermistor is directly embedded in the ceramic substrate to avoid the short-circuit problem caused by electroplating a thermistor exposed and shorten a distance between the thermistor and the crystal oscillation device. Thus, the thermistor can more precisely sense the operating temperature of the crystal oscillation device to timely compensate frequency drift caused by changing the temperature of the crystal oscillation device.

This application claims priority for Taiwan patent application no. 102133155 filed at Sep. 13, 2013, the content of which is incorporated by reference in its entirely.

### BACKGROUND OF THE INVENTION

1. Field of the Invention

The present invention describes a package technology for a crystal oscillator, particularly to a package structure of crystal oscillator with embedded thermistor.

2. Description of the Related Art

A crystal oscillator, especially a quartz crystal oscillator, uses the piezoelectric effect of quartz crystal to create a vibrating signal with precise frequency. Since the quartz crystal oscillator has the advantages of small volume, light weight, high reliability and high stability for frequency and mainly serves as a resonance device in an oscillator circuit which requires very high stability for frequency, the quartz crystal oscillator has found applications in all kinds of electric devices and communicated equipments.

However, the crystal oscillation device used in the quartz crystal oscillator, would result in the drifting of vibrating frequency caused by the temperature variation of. Thus, the quartz crystal oscillator will lose the properties of stabilizing frequency. As a result, a thermistor is installed in the crystal oscillator and used to sense temperature, thereby compensating the frequency drift caused by the changed temperature of the crystal oscillation device through a rear-end circuit. Nowadays, a common package structure of crystal oscillator with a thermistor is shown in FIG. 1.

As shown in FIG. 1, the package structure comprises a ceramic substrate 10 with a top thereof having an upper accommodation space 12 and a bottom thereof having a lower accommodation space 14. A patterned metal interconnection for electrical connection (not shown) is disposed in the ceramic substrate 10 and on inner bottom surfaces of the upper accommodation tank 12 and the lower accommodation tank 14. A crystal oscillation device 16 is mounted in the upper accommodation space 12 of the ceramic substrate 10, and a cover 18 is used to seal the upper accommodation space 12. A thermistor 20 is mounted in the lower accommodation space 14 of the ceramic substrate 10. The crystal oscillation device 16 and the thermistor 20 are electrically connected with external electrode pads 22 through the patterned metal interconnection, and the thermistor 20 is used to sense the temperature of the crystal oscillation device 16, thereby compensating the thermal drifting of vibrating frequency of crystal oscillation device 16.

However, in the package structure of the crystal oscillator, it is a certain distance between the thermistor and the crystal oscillation device. Thus, the distance results in the temperature difference limits the sensing accuracy. Moreover, the thermistor is molded by a process, and then mounted in the lower accommodation space of the ceramic substrate after molding the ceramic substrate. In other words, the additional cost of the molding process is required. To overcome the abovementioned problems, the present invention provides a package structure of crystal oscillator with embedded thermistor, so as to solve the afore-mentioned problems of the prior art.

### SUMMARY OF THE INVENTION

A primary objective of the present invention is to provide a package structure of crystal oscillator with embedded thermistor, which directly forms at least one thermistor in a process for fabricating a substrate, and which directly embeds the thermistor in the substrate to shorten a distance for thermal conduction between the thermistor and a crystal oscillation device and omit an additional fabrication process for installing the thermistor, whereby the cost of fabrication process is reduced.

Another objective of the present invention is to provide a package structure of crystal oscillator with embedded thermistor, which directly embeds at least one thermistor in the substrate. When an electroplating process is performed, the short-circuit problem caused by coating a thermistor on the surface of the substrate is avoid.

To achieve the abovementioned objectives, the present invention provides a package structure of crystal oscillator with embedded thermistor, which comprises a ceramic substrate having an accommodation space. A patterned metal interconnection distributed in the ceramic substrate and on the surface of said substrate within the accommodation space. A crystal oscillation device is mounted in the accommodation space and electrically connected with the patterned metal interconnection. The accommodation space is sealed by a cover. At least, one thermistor is embedded in the ceramic substrate and electrically connected with the patterned metal interconnection in the ceramic substrate. Since the thermistor of the present invention directly embeds in the ceramic substrate, a distance between the thermistor and the crystal oscillation device is shortened as much as possible. Compared with the package structure in the traditional technology, the thermistor can more precisely sense a temperature of the crystal oscillation device to timely compensate frequency drift caused by changing the temperature of the crystal oscillation device.

Below, the embodiments are described in detail in cooperation with the drawings to make easily understood the technical contents, characteristics and accomplishments of the present invention.

### BRIEF DESCRIPTION OF THE DRAWINGS

FIG. 1 is a cross-sectional view showing a package structure of crystal oscillator with thermistor in the traditional technology;

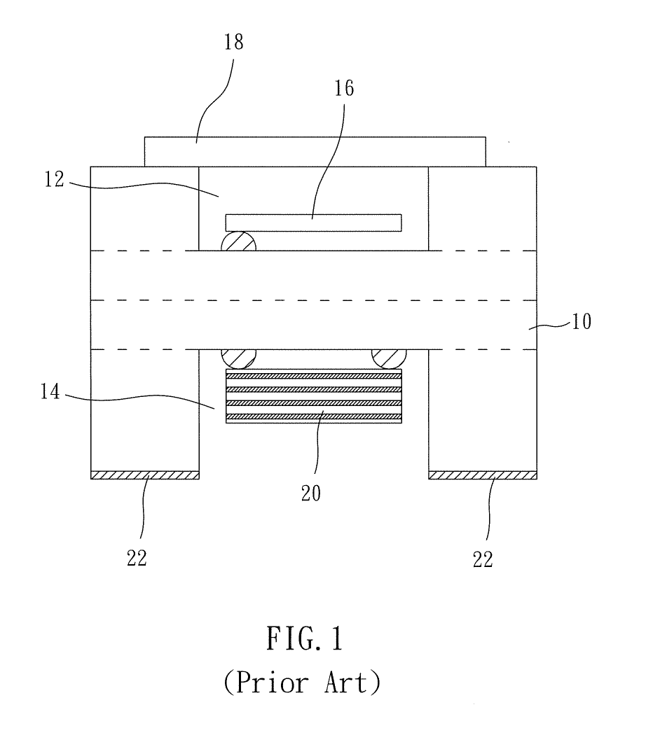

FIG. 2 is a perspective view showing a package structure of crystal oscillator according to an embodiment of the present invention;

FIG. 3 is a cross-sectional view showing the package structure of crystal oscillator according to an embodiment of the present invention;

FIG. 4 is an upward view showing the package structure of crystal oscillator according to an embodiment of the present invention; and

FIG. 5 is a schematic diagram showing a ceramic substrate arranged into a planar array during a fabrication process according to an embodiment of the present invention.

### DETAILED DESCRIPTION OF THE INVENTION

In order to improve the precision of sensing the operation temperature of a crystal oscillation device, the present invention provides a package structure of crystal oscillator with embedded thermistor to shorten a distance between the thermistor and the crystal oscillation device, whereby the thermistor can more precisely sense the operating temperature of the crystal oscillation device.

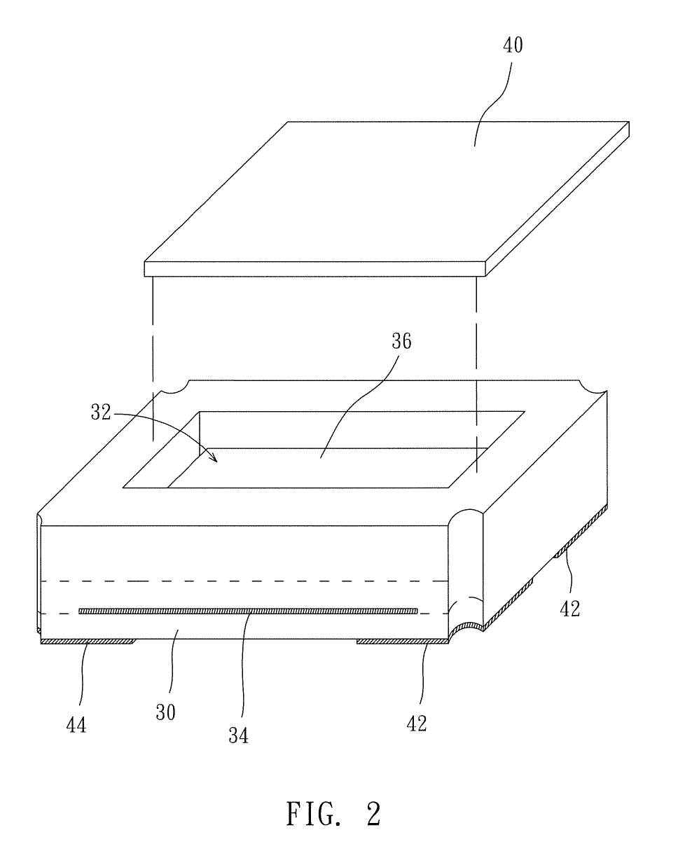

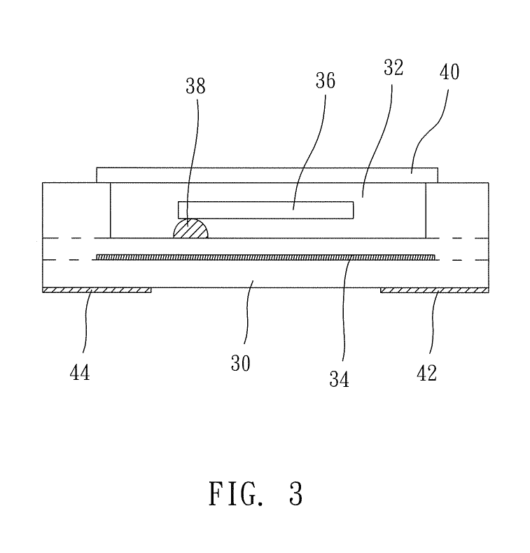

FIG. 2 is a perspective view showing a package structure of crystal oscillator according to an embodiment of the present invention. FIG. 3 is a cross-sectional view showing the package structure of crystal oscillator according to an embodiment of the present invention. Refer to FIG. 2 and FIG. 3. The package structure of crystal oscillator with embedded thermistor of the present invention comprises a substrate, preferably a ceramic substrate 30. The ceramic substrate 30 has an accommodation space 32 disposed thereon. A patterned metal interconnection (not shown) is distributed in the internal layer of the ceramic substrate 30 and on the surface of the ceramic substrate 30 within the accommodation space 32. The patterned metal interconnection and the ceramic substrate 30 are in the integrated fabrication. The patterned metal interconnection is divided into a first patterned metal interconnection and a second patterned metal interconnection. The first patterned metal interconnection is provided to a crystal oscillation device for electric connection. The second patterned metal interconnection is provided a electric connection for thermistor. At least one thermistor 34, for example, but not limited to one thermistor 34, is directly embedded in the ceramic substrate 30 in the embodiment. In the present invention, the packaging structure can use the amount of the thermistor 34 according to a practical requirement such as a resistance value. The thermistor 34 is electrically connected with the first patterned metal interconnection in the ceramic substrate 30. A crystal oscillation device 36, such as a quartz crystal oscillation device, uses a conduction adhesive 38 to be installed on the ceramic substrate 30 and disposed in the accommodation space 32. The crystal oscillation device is electrically connected with the second patterned metal interconnection. A cover 40, such as a metal cover, is installed on the ceramic substrate 30 to envelop the accommodation space 32, thereby sealing the crystal oscillation device 36.

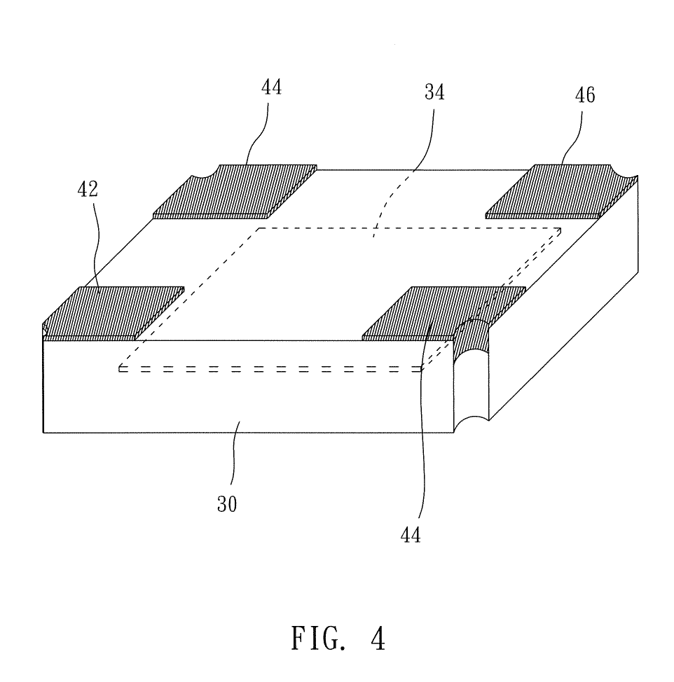

Moreover, a plurality of conduction pads 42, 44 and 46 are disposed on the external surface of the ceramic substrate 30, as shown in FIG. 4. For example, it could use four conduction pads to be the embodiment. The patterned metal interconnection includes the first and second patterned metal interconnections in and on the ceramic substrate 30 respectively electrically connected with the corresponding conduction pads. The first patterned metal interconnection is electrically isolated from the second patterned metal interconnection. The conduction pad 42 is sequentially electrically connected with the first patterned metal interconnection and the thermistor 34 to serve as a conduction pad for sense; and the two conduction pads 44 are sequentially electrically connected with the second patterned metal interconnection and the crystal oscillation device 36 to serve as conduction pads for oscillation. Another conduction pad 46 is a ground pad (GND). In addition, since the present invention directly embeds the thermistor 34 in the ceramic substrate 30 to reduce the volume of the package. The appearance of the package structure is identical to that of a traditional quartz oscillator. The package structure of the present invention is different from that quartz oscillator in the external conduction pad. The conduction pad 42 for sense is added to replace one ground pad of the traditional quartz oscillator.

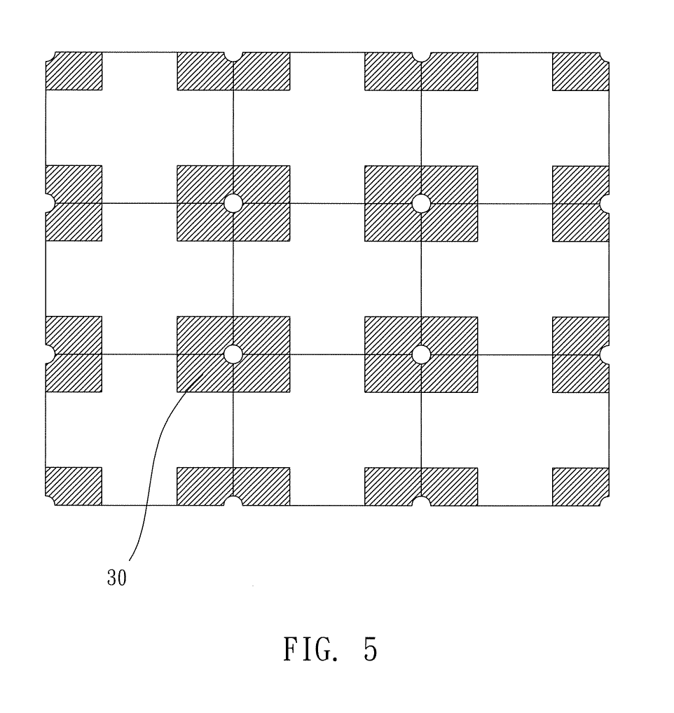

The present invention directly integrates the process for embedding the thermistor 34 in the ceramic substrate 30 in the process of fabricating the ceramic substrate 30. When the ceramic substrate 30 is fabricated, laminationand high-temperature sinter processes of thermistor material are performed in the internal position of the ceramics. Then, the process continues with fabricating the ceramic substrate, thereby directly forming the necessary thermistor in the ceramic substrate. Refer to FIG. 5. Since the ceramic substrates 30 are arranged into a planar array during the fabrication process, gold is electroplated on conductors emerging from the surface of the ceramic substrate 30. If the thermistor is coated on the surface of the ceramic substrate, gold is also electroplated on the thermistor, which results in a short-circuit problem. However, the embedded thermistor of the present invention does not result in the problem. In addition, the thermistor is made of well-known materials. Presently, negative temperature coefficient (NTC) and positive temperature coefficient (PTC) thermistors both exist. As a result, the material is chosen according to different requirement. For example, the PTC thermistor is mainly formed by a sintered body being BaTiO₃, SrTiO₃ or PbTiO₃. Valence of the sintered body can be changed by doping the micro-amount of Nb oxide, Ta oxide, Bi oxide, Sb oxide, Y oxide, La oxide, and etc. Thus, the sintered body becomes a semiconductor. Besides, Mn oxide, Fe oxide, Cu oxide and Cr oxide, which all increases a PTC, and an additive having other function are also doped. The NTC thermistor is made of the ceramic semiconductor formed by mixing, molding and sintering binary or more metal oxide, such as Mn oxide, Cu oxide, Si oxide, Co oxide, Fe oxide, Ni oxide and Zn oxide.

As a result, the present invention uses the package structure to shorten the distance of thermal conduction between the thermistor and the crystal oscillation device, whereby the thermistor can precisely sense the operating temperature of the crystal oscillation device, transmit the operating temperature to an external circuit for reading and operating through the conduction pad for sense, and then transmit the temperature back to the crystal oscillation device. The crystal oscillation device can use the operating temperature to precisely and efficiently compensate the frequency drift caused by the changed temperature of the crystal oscillation device. The present invention can more precisely sense the temperature of crystal oscillation device than the package structure in the traditional technology, and efficiently avoid the short-circuit problem caused by electroplating the thermistor. Additionally, the present invention directly integrates the process for fabricating the thermistor in the ceramic substrate to omit an additional fabrication process for installing the thermistor, whereby the cost of fabrication process is reduced.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A package structure of crystal oscillator with embedded thermistor comprising:
a substrate having an accommodation space disposed thereon;
a patterned metal interconnection distributed in said substrate and on a surface of said substrate within said accommodation space;
at least one thermistor embedded in said substrate and electrically connected with said patterned metal interconnection in said substrate;
a crystal oscillation device mounted on said substrate within said accommodation space and electrically connected with said patterned metal interconnection; and
a cover disposed on said substrate to seal said accommodation space.

2. The package structure of crystal oscillator with embedded thermistor according to claim 1, wherein said substrate is a ceramic substrate.

3. The package structure of crystal oscillator with embedded thermistor according to claim 1, wherein said patterned metal interconnection is divided into a first patterned metal interconnection and a second patterned metal interconnection, and said first patterned metal interconnection is electrically connected at least one thermistor, and said second patterned metal interconnection is electrically connected with said crystal oscillation device.

4. The package structure of crystal oscillator with embedded thermistor according to claim 3, further comprises a plurality of conduction pads disposed on an external surface of said substrate, and respectively electrically connected with said first patterned metal interconnection and said second patterned metal interconnection to at least serve as conduction pads for sensing connection of thermistor and electrical connection of oscillator respectively.

5. The package structure of crystal oscillator with embedded thermistor according to claim 3, wherein said crystal oscillation device uses a conduction adhesive to be mounted on said substrate and electrically connected with said second patterned metal interconnection.

6. The package structure of crystal oscillator with embedded thermistor according to claim 3, wherein at least one of said conduction pads connects to ground.

7. The package structure of crystal oscillator with embedded thermistor according to claim 1, wherein said cover is a metal cover.

8. The package structure of crystal oscillator with embedded thermistor according to claim 1, wherein said crystal oscillation device is a quartz crystal oscillation device.
